(19) United States
(12) Patent Application Publication
(10) Pub. No.: US 2014/0097544 A1
(43) Pub. Date: Apr. 10, 2014

(54) Side Stack Interconnection for Integrated Circuits and The Like

(71) Applicant: Altera Corporation, San Jose, CA (US)

(72) Inventor: Long M. Jon, San Jose, CA (US)

(73) Assignee: ALTERA CORPORATION, San Jose, CA (US)

(21) Appl. No.: 13/645,894

(22) Filed: Oct. 5, 2012

(51) Int. Cl. H01L 25/16; H01L 21/50

(52) U.S. Cl. CPC H01L 25/16; H01L 21/50
USPC 257/774; 438/109

(57) ABSTRACT

In an illustrative embodiment, a plurality of integrated circuits are stacked one on top of the other in a block. A plurality of leads on each integrated circuit is made accessible on a first side of the block. An insulating layer is formed on the first side of the block; electrically conducting vias are formed in the insulating layer and coupled to the leads; a conducting layer is formed on the insulating layer and coupled to the conducting vias; and conducting paths are formed in the conducting layer. Additional layers of insulating layer, conducting vias and conducting layer may be formed on top of the first insulating layer and first conducting layer so as to form more complicated interconnection paths to the leads from the integrated circuits.

### BACKGROUND

This relates to the stacking of integrated circuits and the like.

In recent years, the continuing demand to increase computing resources on a circuit board has led to the stacking of integrated circuits, one on top of the other. In such circumstances, connections between integrated circuits are typically made using through silicon vias (TSVs) that run vertically through the plane of the individual integrated circuits. Use of such TSVs is not without penalty because significant area on the integrated circuit must be devoted to the area taken up by the TSVs as well as additional area (often referred to a Keep Out Zone) surrounding each TSV that is required to avoid stress effects in the semiconductor of the integrated circuit.

### SUMMARY

The present invention relates to an improved method and structure for interconnecting stacked circuits such as integrated circuits.

In an illustrative embodiment, a plurality of integrated circuits are stacked one on top of the other in a block. A plurality of leads on each integrated circuit is made accessible on a first side of the block. An insulating layer is formed on the first side of the block; electrically conducting vias are formed in the insulating layer and coupled to the leads; an electrically conducting layer is formed on the insulating layer and coupled to the conducting vias; and conducting paths are formed in the conducting layer. Additional layers of insulating layer, conducting vias and conducting layer may be formed on top of the first insulating layer and first conducting layer so as to form more complicated interconnection paths to the leads from the integrated circuits.

### BRIEF DESCRIPTION OF THE DRAWINGS

These and other objects and advantages of the present invention will be apparent to those of ordinary skill in the art in view of the following detailed description in which:

FIGS. 1A and 1B are a top view and a cross-section of an illustrative embodiment of an integrated circuit used in the practice of the invention;

FIG. 2 is a flowchart depicting an illustrative method of the invention;

FIGS. 3A-3G depict illustrative examples of integrated circuit stacks being formed at various stages in the process of FIG. 2; and

FIGS. 4A-4B depict alternative stack configurations.

It will be appreciated that the drawings are not to scale.

### DETAILED DESCRIPTION

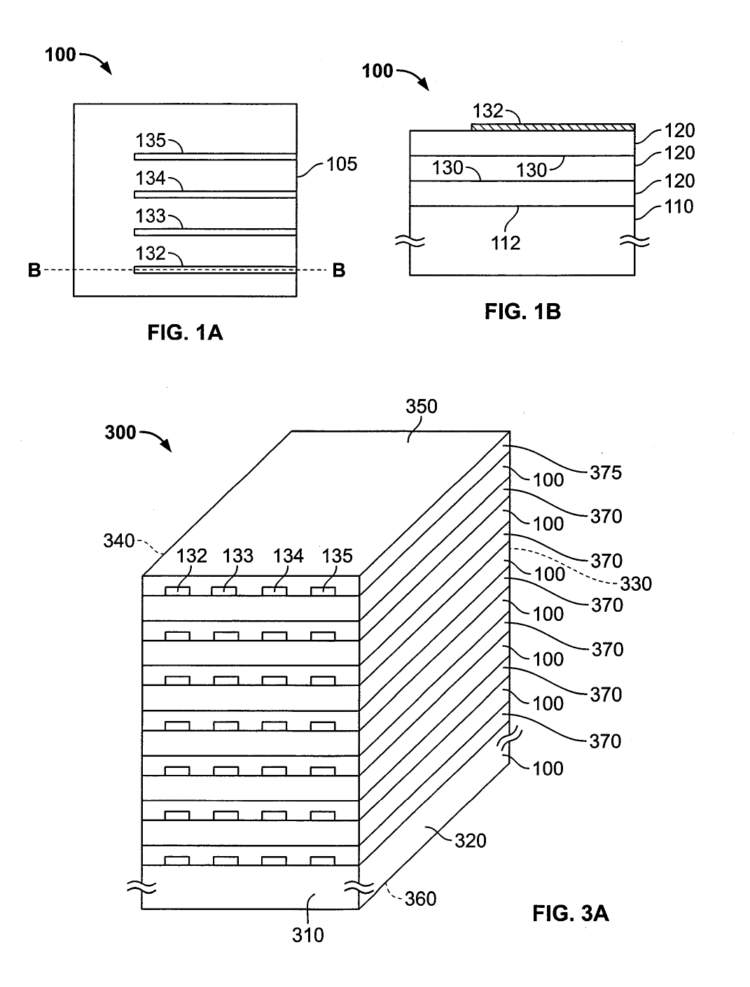

FIGS. 1A and 1B depict an illustrative embodiment of an integrated circuit 100 used in the process of the invention. It will be understood that the starting material for forming the integrated circuit is a semiconductor substrate that typically is a wafer of silicon up to 12 inches (300 millimeters (mm.)) in diameter in today's state-of-the-art processes. A large number of identical integrated circuits are formed in one surface of the semiconductor substrate using technologies well known in the art. Further details concerning such technologies are set forth in S. A. Campbell, The Science and Engineering of Microelectronic Fabrication (2^{nd} ed.)(Oxford 2001); J. D. Plummer et al., Silicon VLSI Technology Fundamentals, Practice and Modeling (Prentice Hall 2000); M. T. Bohr, et al., “The High-k Solution”, IEEE Spectrum (October 2007); E. P. Gusev et al, “Advanced High-k Dielectric Stacks with PolySi and Metal Gates: Recent Progress and Current Challenges,” IBM J. Res. & Dev., Vol. 50, No. 4/5 (July/September 2006), all of which are incorporated by reference herein in their entireties.

Typically, each integrated circuit is rectangular and measures less than an inch (25 mm.) on each side. As a result, several hundred identical integrated circuits are typically formed on a single semiconductor wafer. The integrated circuits are typically aligned in rows and columns on the wafer. After the integrated circuits are formed, the wafer is scribed along the rows and columns and broken apart along the scribe lines so as to separate, or singulate, the individual integrated circuits.

In the typical integrated circuit, bonding pads are formed on at least one of the two major surfaces of the integrated circuit; and the integrated circuit is connected to other circuits such as other integrated circuits or printed circuit boards by connections made to the bonding pads. The bonding pads, in turn, are connected to various circuit elements in the integrated circuit by electrically conducting paths formed in insulating layers located between the bonding pads and the circuit elements formed in the semiconductor substrate. In the present invention, the connections to the circuit elements formed in the semiconductor substrate are made by conducting paths that are brought out to one of the four sides of the integrated circuit as described below.

FIG. 1A depicts a top view of an illustrative integrated circuit 100 used in the practice of the invention. FIG. 1B depicts a cross-section along lines B-B of FIG. 1A. Circuit 100 comprises a semiconductor substrate 110 and one or more insulating layers 120 on one major surface 112 of substrate 110. Various active circuit elements such as MOS or bipolar transistors and passive circuit elements such as resistors, capacitors and the like, are formed in substrate 110 near surface 112. Electrically conducting paths 130 are formed in the insulating layers to couple the transistors and passive elements to each other and to structures external to the integrated circuit. As shown in FIGS. 1A and 1B, some electrically conducting paths 132-135 extend to a first side, side 105, of integrated circuit 100.

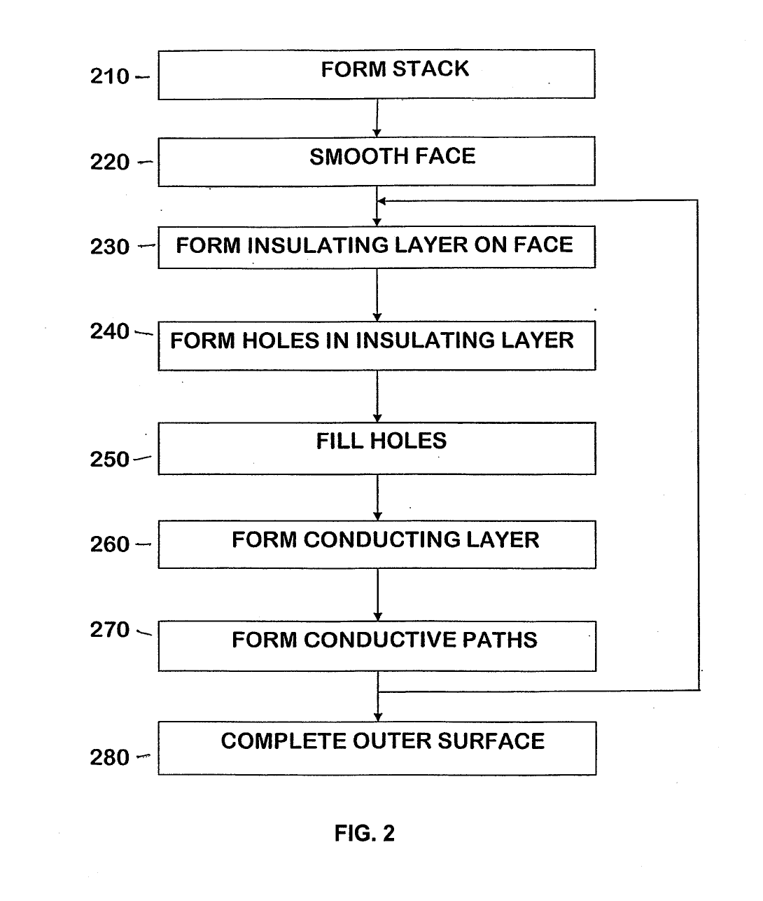

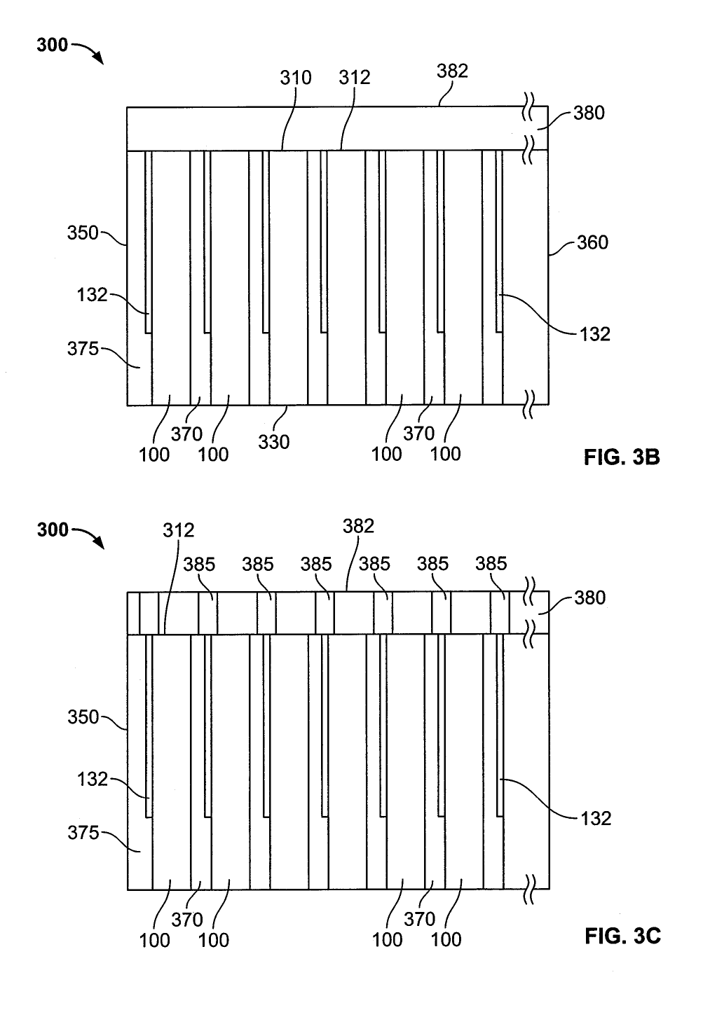

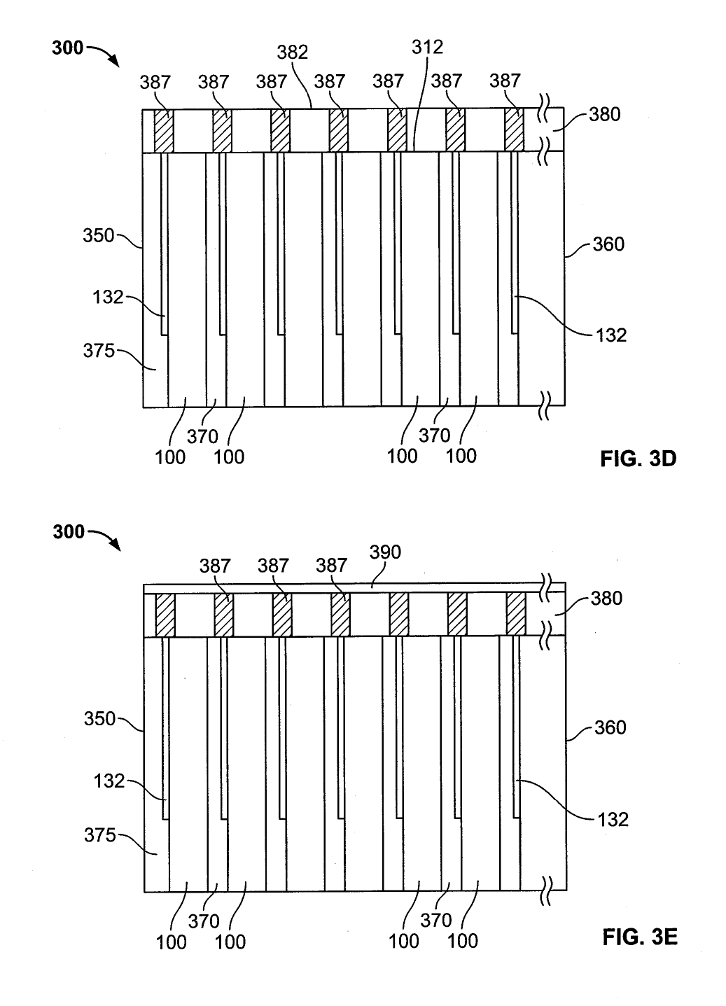

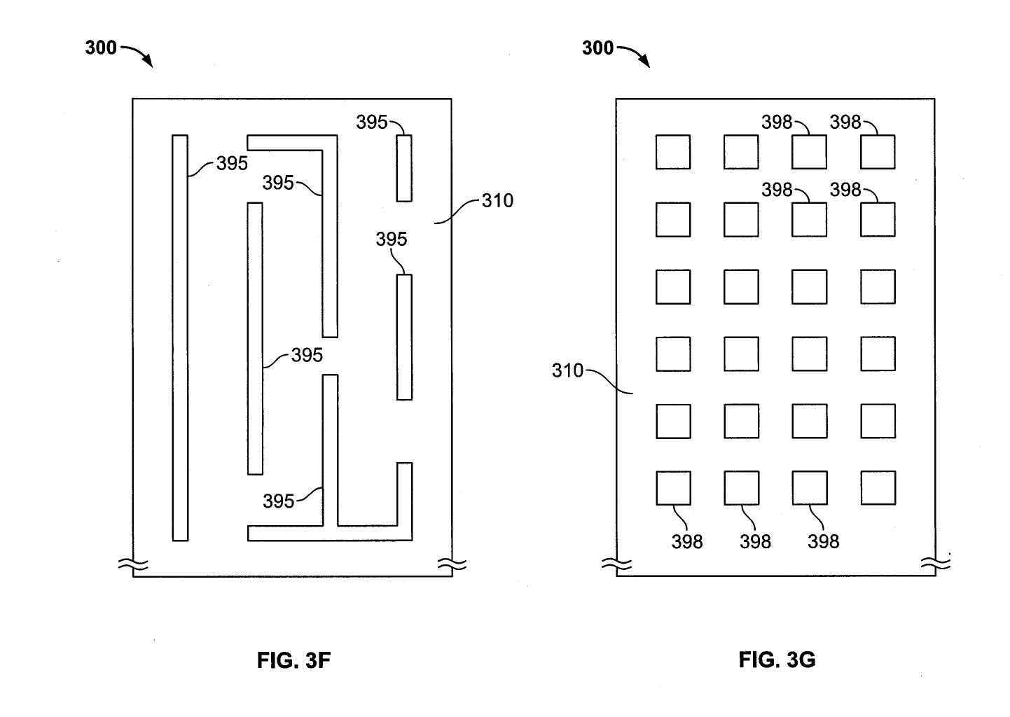

FIG. 2 is a flowchart depicting an illustrative embodiment of a process of the invention. FIGS. 3A-3G depict a stack of integrated circuits at various stages in the process of FIG. 2. At step 210 a plurality of individual integrated circuits such as circuit 100 are oriented, stacked, and glued together to form an integrated circuit stack 300 in which individual electrically conducting paths 132-135 on circuits 100 extend to the same side of the stack. Thus, as shown in FIG. 3A, stack 300 is a rectangular parallelepiped having four faces 310, 320, 330, 340, a top 350, and a bottom 360, with individual integrated circuits 100 of the same size and shape. A glue layer or layers 370 secures each integrated circuit 100 to adjacent integrated circuits in the stack. Illustratively, each glue layer is a thermosetting polymer that has good self-planarization, good adhesion, low susceptibility to cracking and low moisture absorption. Examples of such polymers are benzocyclobutene and SU-8 3000. At the top of the stack, a passivation layer 375 protects the conducting paths on the uppermost integrated circuit 100.

Each integrated circuit 100 has electrically conducting paths that extend to the same face of the stack. For illustrative purposes, for each integrated circuit, four such paths 132-135 are shown extending to face 310 of stack 300. It will be understood, however, that four paths is only illustrative and that the invention may be practiced with other numbers of paths and, most likely, considerably more paths extending to one side of the stack.

In some embodiments of the invention, the individual integrated circuits may be identical. In other embodiments, different integrated circuits and even different types of circuits may be used. By way of example but not limitation, some circuits may be memory circuits and other circuits may be logic circuits. Or, by way of example but not limitation, some circuits may have been made with different semiconductor fabrication technologies, or have different capabilities, different capacities, or different operating speeds. Some circuits may comprise only passive elements. Some may process optical signals. Indeed, not all circuits need to be integrated circuits. In cases where different circuits are used in the same stack, the number of conducting paths extending to the face of the stack from these different circuits may well be different.

At step 220, the face to which the conducting paths extend is prepared for further processing. This involves exposing the ends of the conducting paths and forming a substantially smooth work surface on that face of the stack to which the conducting paths extend. Illustratively, the substantially smooth work surface is formed by chemical mechanical polishing.

At step 230, an insulating layer is formed on the work surface. FIG. 3B depicts stack 300 from side 340 at the depth of conducting paths 132 after the stack has been rotated 90 degrees so that side 310 is facing upwards. Integrated circuits 100, glue layers 370 and conducting paths 132 have the same element numbers as in FIG. 3A. The substantially smooth work surface formed on face 310 is identified as element 312. The insulating layer, which illustratively is a silicon dioxide layer or a phosphosilicate glass, is identified as element 380.

At step 240, holes 385 are formed in insulating layer 380. As shown in FIG. 3C, holes 385 extend from an outer surface 382 of insulating layer 380 to the work surface 312 where they intersect with the conducting paths 132-135.

At step 250, holes 385 are filled with a conducting material such as copper thereby making ohmic connections with conducting paths 132-135. Illustratively, the holes are filled by a blanket deposition of the conducting material which fills the holes and covers the insulating layer 380 as well. The material deposited on the outer surface of the insulating layer is then removed so as to leave in the holes isolated conducting vias 387 that connect to the conducting paths 132-135 as shown in FIG. 3D.

At step 260, a conducting layer 390 is formed on the outer surface 382 of insulating layer 380 and on the conducting vias 387 as shown in FIG. 3E. Illustratively, the conducting layer may be a metal such as aluminum, copper, or copper-doped aluminum.

At step 270, conducting layer 390 is processed to form individual conducting paths 395 as shown in FIG. 3F that connect to the conducting vias 387. FIG. 3F is a view looking directly at face 310 of stack 300. It will be appreciated that the specific paths shown in FIG. 3F are only illustrative. The processing that is performed uses conventional photolithographic techniques well known in the art. These techniques produce the removal of portions of the conducting layer 390 down to the outer surface 382 of the insulating layer 380; and the portions of the conducting layer that remain constitute the conducting paths 395.

Steps 230-270 may then be repeated several times more to build up additional layers of insulating material and conducting paths. Thus, another insulating layer may be formed on top of the conducting paths and the exposed surface 382 of insulating layer 380. Holes may be formed in the insulating layer that extend from the upper surface of the insulating layer to points of intersection with the conducting paths 395. The holes may be filled with a conducting material to form isolated conducting vias. A conducting layer may be formed on the outer surface of the insulating layer; and the conducting layer may be processed to form another layer of conducting paths similar to paths 395 that connect to the conducting vias and, ultimately, to the conducting paths 132-135.

This process may be repeated to form many layers of conducting paths that ultimately couple to the conducting leads on the integrated circuits 100 in the stack. Finally, at step 280, bonding pads 398 are formed on the outer surface to provide connections between the conducting paths and structures external to the block; and the outer surface is provided with a passivation layer to protect the structure. FIG. 3G is a face view similar to that of FIG. 3F but depicting the outside of face 310 with bonding pads 398.

As will be apparent to those skilled in the art, numerous variations may be practiced within the spirit and scope of the present invention. For example, while the invention has been described in the context of silicon fabrication technology, the invention may also be practiced for other semiconductor fabrication technologies such as Gallium Arsenide and other III-V material systems. Specific details for the formation of the insulating layer, the conducting vias, and the conducting layer have not been supplied because many such processes are well known in the industry. For example, details of many of these processes are set forth in the above-referenced textbooks of Campbell and Plummer, which are incorporated by reference herein. While the embodiments have been described in terms of single layers, it will be understood that the single layers may be formed of multiple sub-layers that provide a multiplicity of functions.

In the interest of simplicity and to avoid obscuring the invention, only the major steps of the semiconductor fabrication process have been described. It will also be understood that many additional steps and details have been omitted as unnecessary for an understanding of the invention.

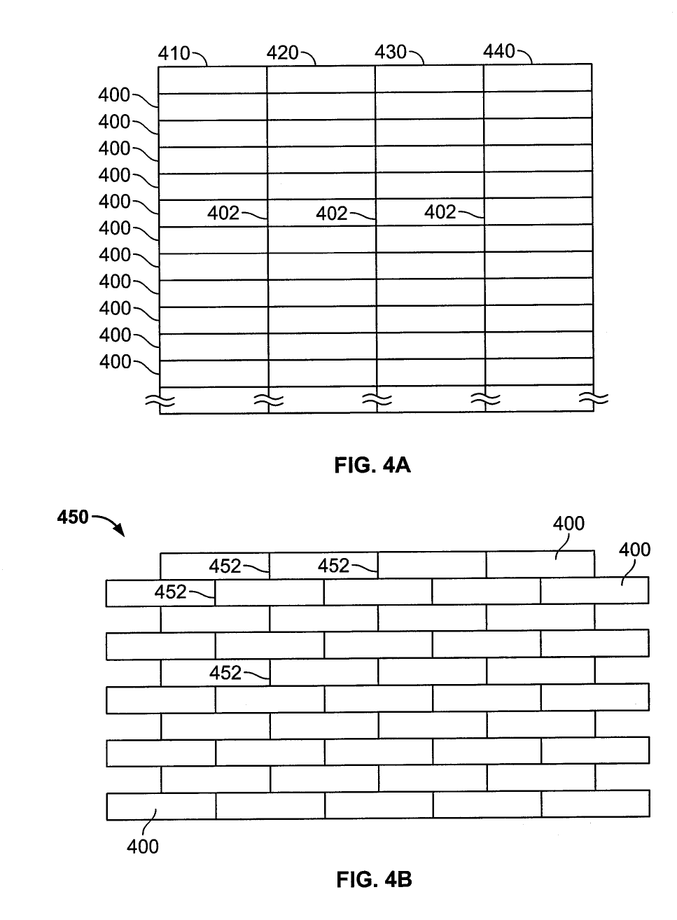

While the invention has been described for the case of a single stack of circuits, the invention may be practiced using a variety of arrangements for stacking the circuits. In addition to the “one-dimensional” stack depicted in FIGS. 3A-3G, the invention may also be practiced with “two-dimensional” stacks. For example, instead of arranging the circuits in a single vertical column, the circuits could be arranged in multiple columns 410, 420, 430, 440 as shown in FIG. 4A, thereby adding a horizontal component to the stacking structure. In this embodiment, each of columns 410, 420, 430, 440 might be similar to stack 300 comprising a plurality of cells 400, each of which includes a substrate such as circuit 100, one or more insulating layers such as layers 120 on the substrate, a plurality of electrically conducting paths such as paths 132-135 that are located in the insulating layers and extend to one face of the stack, and a glue layer such as glue layer 370 that secures the substrate to the next substrate in the stack. Instead of a glue layer, the uppermost cell in each stack has a passivation layer similar to layer 375 to protect the conducting paths on the uppermost cell. An additional glue layer 402 is used to secure each stack to its adjacent stack(s).

Moreover, instead of the arrangement shown in FIG. 4A where the edges of the cells in each layer are aligned with the edges of the cells in the next layer, the cells in adjacent layers could be over-lapped (or staggered), as bricks are typically over-lapped in a brick wall, thereby forming a structure that is mechanically more secure. One such alternative arrangement is depicted in FIG. 4B. It comprises 45 cells 400 in a structure 450 that is five circuits wide and ten circuits high. The cells of FIG. 4B may be similar to cells 400 of FIG. 4A and accordingly have the same element number. Each cell 400 is secured to adjacent cell(s) in the same layer by a glue layer 452.

Cells 400 may be identical; or, as indicated above, different types of circuits may be combined in one structure. For example, different types of integrated circuits such as logic circuits and memory circuits might be combined in a single structure such as that shown in FIG. 4A or FIG. 4B. Circuits made with different semiconductor fabrication technologies, or having, by way of example but not limitation, different capabilities, different capacities, or different operating speeds may be combined in a single structure Likewise, circuits that comprise only passive elements may be included in structures 410-450 as well as circuits for processing optical signals. To accommodate temperature variations, it is recommended that the cells be made of the same material or of materials having similar thermal coefficients of expansion over the expected operating temperature range of the structure.

In the structures shown in FIGS. 4A and 4B, each cell has the same height and width. However, as in the construction of a brick wall, cells having different heights and/or widths can be accommodated by appropriate combinations of different sized cells. Cells having different depths can be used in the structures of FIGS. 4A and 4B.

Still other variations may be practiced within the spirit and scope of the invention.

What is claimed is:

1. A method for forming an integrated circuit structure comprising:
assembling a plurality of integrated circuits in a stack, the integrated circuits having conducting paths that extend to a first side of the stack;
forming an insulating layer on the first side of the stack; and
forming conducting pathways in the insulating layer that couple to the conducting paths of the integrated circuits.

2. The method of claim 1 further comprising planarizing the first side of the stack before forming the insulating layer so as to expose the conducting paths that extend to the first side.

3. The method of claim 1 further comprising:
forming holes in the insulating layer that extend from an outer surface of the insulating layer to the conducting paths; and
forming conducting vias in the holes that connect to the conducting paths.

4. The method of claim 1 wherein the step of forming conducting pathways in the insulating layer comprises:
forming conducting vias that extend through the insulating layer and connect to the conducting paths;
forming on a surface of the insulating layer a conducting layer that connects to the conducting vias; and
forming pathways in the conducting layer on the surface of the insulating layer.

5. The method of claim 1 wherein the step of forming conducting pathways in the insulating layer comprises:
forming holes in the insulating layer that extend from an outer surface of the insulating layer to the conducting paths;
forming conducting vias in the holes that connect to the conducting paths;
forming on a surface of the insulating layer a conducting layer that connects to the conducting vias; and
forming pathways in the conducting layer on the surface of the insulating layer.

6. The method of claim 1 further comprising the step of gluing the integrated circuits to form the stack.

7. A method for forming a semiconductor device comprising:
assembling a plurality of integrated circuits in a stack, each integrated circuit comprising a semiconductor substrate and a plurality of first conducting paths separated by at least a first insulating region formed on the substrate;
forming a second insulating region on a first side of the stack; and
forming second conducting paths in the second insulating region that couple to the first conducting paths.

8. The method of claim 7 further comprising planarizing the first side of the stack before forming the second insulating region so as to expose the first conducting paths.

9. The method of claim 7 further comprising:
forming holes in the second insulating region that extend from an outer surface of the second insulating region to the first conducting paths; and
forming conducting vias in the holes that connect to the first conducting paths.

10. The method of claim 7 wherein the step of forming second conducting paths in the second insulating region comprises:
forming conducting vias that extend through the second insulating region and connect to the first conducting paths;
forming on a surface of the second insulating region a conducting layer that connects to the conducting vias; and
defining pathways in the conducting layer on the surface of the second insulating region.

11. The method of claim 7 wherein the step of forming second conducting paths in the insulating layer comprises:
forming holes in the second insulating region that extend from an outer surface of the second insulating region to the first conducting paths;
forming conducting vias in the holes that connect to the first conducting paths;
forming on a surface of the second insulating region a conducting layer that connects to the conducting vias; and
forming pathways in the conducting layer on the surface of the second insulating region.

12. The method of claim 7 further comprising the step of gluing the integrated circuits to form the stack.

13. The method of claim 7 further comprising the steps of:
forming a third insulating region on the second insulating region; and
forming third conducting paths in the third insulating region that couple to the second conducting paths.

14. A semiconductor device comprising:
a plurality of integrated circuits stacked one on top of the other to form a stack,
each integrated circuit comprising a semiconductor substrate and a plurality of first conducting paths separated by at least a first insulating region formed on the substrate,
a second insulating region on a first side of the stack, and
a plurality of second conducting paths formed in the second insulating region and coupling to the plurality of first conducting paths.

15. The semiconductor device of claim 14 further comprising an adhesive layer between the integrated circuits.

16. The semiconductor device of claim 14 wherein the second conducting paths are formed in a metallization layer on the second insulating layer.

17. The semiconductor device of claim 14: wherein the second conducting paths comprise:
conducting vias that extend through the second insulating layer and connect to the first conducting paths; and
pathways that are defined in a conducting layer on a surface of the second insulating layer and connect to the conducting vias.

18. The semiconductor device of claim 14 further comprising:
a third insulating region on the second insulating layer, and
a plurality of third conducting paths formed in the third insulating region and coupling to the plurality of second conducting paths.

19. The semiconductor device of claim 14 wherein the plurality of first conducting paths extend to the first side of the stack.

20. A semiconductor device comprising:
a plurality of circuits each having first conducting paths on a first surface thereof, said circuits being stacked on one another in two dimensions to form a block having at least two layers in which at least two circuits are in each layer, at least a plurality of said circuits being integrated circuits;
an insulating layer on a first side of the block; and
second conducting paths extending through the insulating layer and coupling to the first conducting paths.

21. The device of claim 20 further comprising an adhesive layer between the circuits.

22. The device of claim 20 wherein the second conducting paths are formed in a metallization layer on the insulating layer.

23. The device of claim 20 wherein the second conducting paths comprise:
conducting vias that extend through the insulating layer and connect to the first conducting paths; and
pathways that are defined in a conducting layer on a surface of the insulating layer and connect to the conducting vias.

24. The device of claim 20 wherein the plurality of first conducting paths extend to the first side.

25. The device of claim 20 wherein the layers of circuits are arranged so that edges of the circuits are aligned with one another.

26. The device of claim 20 wherein the layers of circuits are arranged so that edges of the circuits in adjacent layers are not aligned with one another.

27. The device of claim 20 wherein each of the circuits in the block is an integrated circuit.
